(19) United States
(12) Patent Application Publication
(10) Pub. No.: US 2023/0402559 A1
(43) Pub. Date: Dec. 14, 2023

(54) FLUORESCENT LIGHT-GUIDING PLATE AND METHOD OF MANUFACTURING THE SAME

(71) Applicant: TOYOTA JIDOSHA KABUSHIKI KAISHA, Toyota-shi (JP)

(72) Inventors: Taizo MASUDA, Yokohama-shi (JP); Kenichi OKUMURA, Gotemba-shi (JP); Ryota TOMIZAWA, Mishima-shi (JP)

(73) Assignee: TOYOTA JIDOSHA KABUSHIKI KAISHA, Toyota-shi (JP)

(21) Appl. No.: 18/124,686

(22) Filed: Mar. 22, 2023

(30) Foreign Application Priority Data
Jun. 9, 2022 (JP) 2022-094020

(51) Int. Cl. H01L 31/055; H01L 31/0352

(52) U.S. Cl. CPC H01L 31/055; H01L 31/035218

(57) ABSTRACT

A fluorescent light-guiding plate is defined by a first surface, a second surface, and edge surfaces, has a platy structure in which quantum dots that absorb at least one or some of components of sunlight and radiate fluorescence are internally dispersed and which is formed of a material different in refractive index from an outside, and allows the fluorescence radiated from the quantum dots to be concentrated onto the edge surfaces and emitted when the sunlight is incident from the first surface. The platy structure is formed by laminating thin resin films in which the quantum dots are dispersed. The thin resin films are formed by spreading out a solution of quantum dots and resin with an organic solvent in which the quantum dots covered with an aggregation inhibitor and a resin material are dispersed, into a thin-film shape, to evaporate the organic solvent and cure the resin material.

### CROSS-REFERENCE TO RELATED APPLICATION

This application claims priority to Japanese Patent Application No. 2022-094020 filed on Jun. 9, 2022, incorporated herein by reference in its entirety.

### BACKGROUND

### 1. Technical Field

The disclosure relates to a fluorescent light-guiding plate utilizable for a photoelectric conversion device configured to concentrate sunlight and irradiate photoelectric cells with the sunlight, and a method of manufacturing the fluorescent light-guiding plate. More particularly, the disclosure relates to a fluorescent light-guiding plate in which quantum dots are adopted as a fluorescent substance dispersed in the plate, and a method of manufacturing the fluorescent light-guiding plate.

### 2. Description of Related Art

In a photovoltaic power generation system, various configurations have been proposed to concentrate sunlight, which is low in intensity in itself, and irradiate photoelectric cells such as photovoltaic cells with the sunlight, with a view to decreasing the number of photoelectric cells to be utilized and hence reducing the cost or dimension of the system, while increasing the amount of power generation per each of the photoelectric cells or enhancing the power generation efficiency in the system. For example, Japanese Unexamined Patent Application Publication No. 2016-131249 (JP 2016-131249 A) discloses a photovoltaic power generator with photovoltaic cells attached to lateral surfaces of a light-emitting converter configured such that magic-sized clusters as light-emitting bodies are embedded in a platy, transparent light-guiding element or embedded in a thin film on the surface of a transparent light-guiding element. In this photovoltaic power generator, when the light-guiding element is irradiated with sunlight, the sunlight is absorbed by the light-emitting bodies, light is radiated again from the light-emitting bodies in all the directions, most of the light radiated again is introduced onto lateral surfaces of the light-guiding element through internal reflection in a plate of the light-guiding element, and the energy of sunlight is converted into electric energy in the attached photovoltaic cells. According to this configuration, the energy of the sunlight with which a wide area of the surface of the light-guiding element has been irradiated is concentrated onto small areas of the lateral surfaces of the light-guiding element, and can be recovered by the small-area photovoltaic cells covering the lateral surfaces respectively. Therefore, an advantage is gained in terms of economy. Besides, Japanese Unexamined Patent Application Publication No. 2022-062642 (JP 2022-062642 A) by the applicant of the present application discloses the following configuration of a photoelectric conversion device that concentrates sunlight and irradiates photoelectric cells with the sunlight to carry out photovoltaic power generation in the photoelectric cells. The photoelectric conversion device has a platy structure formed of a material in which a fluorescent substance that absorbs sunlight and radiates fluorescence is dispersed and which is different in refractive index from an outside. The photoelectric conversion device is configured to include a fluorescent light-guiding plate having edge surfaces onto which the fluorescence radiated from the fluorescent substance is concentrated before being emitted when the sunlight is incident from one surface of the platy structure, a first photoelectric cell that is placed on a surface of the fluorescent light-guiding plate to generate power upon being irradiated with the sunlight, a lens layer that is superimposed on the fluorescent light-guiding plate and the first photoelectric cell and configured such that the light incident from an outer surface of the lens layer is concentrated onto the first photoelectric cell, and a second photoelectric cell that generates power upon being irradiated with the fluorescence emitted from one of the edge surfaces of the fluorescent light-guiding plate. In this photoelectric conversion device, the sunlight with which an upper surface of the photoelectric conversion device is irradiated by the lens layer is concentrated onto a light-receiving surface of the first photoelectric cell, the light that has failed to reach the light-receiving surface of the first photoelectric cell is absorbed by the fluorescent substance and converted into fluorescence, and the fluorescence is concentrated onto the second photoelectric cell arranged on the edge surface of the fluorescent light-guiding plate. Thus, even when the orientation of the sunlight changes, a maximum possible amount of sunlight energy is recovered. Incidentally, a configuration similar to that of the fluorescent light-guiding plate in the photoelectric conversion device of JP 2022-062642 A is also utilized in a solar-pumped laser device of Japanese Unexamined Patent Application Publication No. 2017-168662 (JP 2017-168662 A) by the applicant of the present application.

### SUMMARY

By the way, as for the fluorescent substance in the fluorescent light-guiding plate used to concentrate sunlight as described above, the quantum dots have a long absorption wavelength, a short light emission wavelength, and high quantum efficiency. Therefore, the quantum dots are advantageously used as the fluorescent substance for converting sunlight having a wide band of wavelength into fluorescence. Typically, in forming a fluorescent light-guiding plate in which such quantum dots are dispersed, a transparent or translucent resin material is mixed into a solution with an organic solvent such as toluene in which the quantum dots are dispersed. After that, while evaporating the organic solvent, the resin material is cured. Thus, a platy member in which the quantum dots are dispersed is formed.

In this regard, according to the studies conducted by the inventors of the disclosure, it has been found out that when the organic solvent containing the quantum dots and the resin material (a solution of quantum dots and resin) is directly cured into a platy structure with a thickness (e.g., equal to or larger than about 3 mm) that allows the solution to be used as the fluorescent light-guiding plate, the ratio of light intensity obtained on edge surfaces of the platy structure to the intensity of the light with which a light-receiving surface of the platy structure has been irradiated (hereinafter referred to as “the light emission intensity per irradiation light intensity”) substantially decreases to, for example, about one-fourteenth of that in the case of the state of the solution in a container having the same dimension as the platy structure. This is considered to result from the fact that when the platy member of the cured resin is thick enough to allow the use thereof as the fluorescent light-guiding plate, it takes a certain length of time (usually about 24 hours) to evaporate the organic solvent from the solution of quantum dots and resin and complete the curing of the resin material, an aggregation inhibitor (a fatty acid such as oleic acid) covering the peripheries of the quantum dots comes off in the meantime, the quantum dots aggregate, and the absorption efficiency or light emission efficiency of the quantum dots falls (the quantum dots deteriorate) etc. Thus, the inventors of the disclosure conducted studies on the process of creating the fluorescent light-guiding plate from the solution of quantum dots and resin. As a result, it has been found out that, in the fluorescent light-guiding plate formed by spreading out the solution of quantum dots and resin into a thin-film shape, swiftly curing the solution, and laminating such thin films into the platy structure, the light emission intensity per irradiation light intensity is substantially higher than, for example, 10 to 12 times as high as that in the case where the solution of quantum dots and resin is directly cured into the thickness of the fluorescent light-guiding plate. This is considered to result from, for example, the fact that the resin is cured in a shorter period of time and hence the aggregation of the quantum dots can be suppressed or avoided in the case where the solution of quantum dots and resin is cured into the thin-film shape. This knowledge is utilized in the disclosure.

It is thus a main task of the disclosure to enhance the light emission intensity per irradiation light intensity in a fluorescent light-guiding plate using quantum dots as a fluorescent substance.

According to one aspect of the disclosure, the aforementioned task is achieved by a fluorescent light-guiding plate that is defined by a first surface, a second surface, and edge surfaces connecting peripheral edges of the first surface and the second surface to each other. The fluorescent light-guiding plate has a platy structure in which quantum dots that absorb at least one or some of components of sunlight and radiate fluorescence are internally dispersed and which is formed of a material different in refractive index from an outside, and allows the fluorescence radiated from the quantum dots to be concentrated on the edge surfaces and emitted when the sunlight is incident from the first surface. The platy structure is established by laminating thin resin films in which the quantum dots are dispersed.

In the foregoing configuration, “the fluorescent light-guiding plate” is basically a platy member configured such that when light is incident from a wide surface (the first surface) of the platy structure, a fluorescent substance dispersed in the plate is excited by the light to emit fluorescence, and the fluorescence is introduced and concentrated onto edge surfaces of the platy structure and goes out. The fluorescence radiated by the fluorescent substance is emitted from the fluorescent substance in a radial direction. When the refractive index of the platy structure constituting the fluorescent light-guiding plate is different from the refractive index of an area outside the platy structure, part of the fluorescence permeates an interface between the wide surfaces (the first surface and the second surface) of the platy structure and the outside, but the rest of the fluorescence is reflected (a substantial amount of fluorescence is reflected through total reflection when the refractive index of the fluorescent light-guiding plate is higher than the refractive index of the outside), and as a result, most of the light is concentrated onto the edge surfaces of the platy structure, and emitted therefrom. In this fluorescent light-guiding plate, the quantum dots are used as “the fluorescent substance” dispersed inside the platy structure, especially in the disclosure.

Moreover, in the case of the fluorescent light-guiding plate of the disclosure, the platy structure is configured such that thin resin films in which the quantum dots are dispersed are laminated, as described above. As mentioned already, in the case where the solution of quantum dots and resin is directly cured into the platy structure in which the quantum dots are dispersed in the fluorescent light-guiding plate, a deterioration in the quantum dots is caused. On the other hand, it has been found out that the light emission intensity of the quantum dots per irradiation light intensity is increased substantially, for example, about 10 to 12 times in the case where, for example, the solution of quantum dots and resin is thinly spread out etc. to form the platy structure configured such that the thin resin films in which the quantum dots are dispersed are laminated. Thus, in the fluorescent light-guiding plate of the disclosure, as described above, the platy structure configured such that the thin resin films in which the quantum dots are dispersed are laminated is adopted to increase the light emission intensity per irradiation light intensity in the fluorescent light-guiding plate. Incidentally, any one of, for example, CdSe, CdTe, PbS, perovskite quantum dots (CsPbX₃, X=Cl, Br, I or the like) can be utilized as the quantum dots. A matrix resin for the thin resin films may be any transparent or translucent solid resin that exhibits appropriate rigidity when cured. For example, the matrix resin may be a fluorine resin such as 4 ethylene fluoride-ethylene copolymer (ETFE) or polymethyl methacrylate resin, but is not limited thereto.

In an aspect of implementation, the platy structure configured such that the thin resin films are laminated in the aforementioned fluorescent light-guiding plate of the disclosure may be established such that the thin resin films and a plurality of transparent or translucent film materials are laminated alternately. One of the thin resin films may have a thickness smaller than 1 mm, and typically a thickness of about several tenths of mm. In handling such thin films only, troublesomeness or difficulty such as a rupture in the thin films is encountered. Therefore, the handling of the platy structure can be further facilitated by alternately laminating the transparent or translucent film materials and the thin resin films to establish the platy structure. Any transparent or translucent films such as polyester films may be adopted as the transparent or translucent film materials.

The aforementioned thin resin films constituting the platy structure of the fluorescent light-guiding plate of the disclosure may be formed according to any method of, for example, thinly spreading out, drying, and curing a solution of quantum dots and resin with an organic solvent in which quantum dots and a resin material are dispersed, as mentioned already. Accordingly, according to another aspect, the task of the disclosure is achieved by a method of manufacturing a fluorescent light-guiding plate that is defined by a first surface, a second surface, and edge surfaces connecting peripheral edges of the first surface and the second surface to each other, that has a platy structure in which quantum dots that absorb at least one or some of components of sunlight and radiate fluorescence are internally dispersed and which is formed of a material different in refractive index from an outside, and that allows the fluorescence radiated from the quantum dots to be concentrated onto the edge surfaces and emitted when the sunlight is incident from the first surface. The method includes a first process of preparing a solution of quantum dots and resin with an organic solvent in which the quantum dots covered with an aggregation inhibitor and a resin material are dispersed, a second process of forming thin resin films in which the quantum dots are dispersed, from the solution of quantum dots and resin, and a third process of laminating the thin resin films to form the platy structure.

In the foregoing configuration, “the organic solvent” may be any organic solvent that can be used to disperse quantum dots such as toluene. Incidentally, when aggregated in a solution, the quantum dots may change in absorption characteristics or light emission characteristics or deteriorate. Therefore, when the quantum dots are dispersed in the organic solvent, an aggregation inhibitor is added thereto. As the aggregation inhibitor, for example, a fatty acid having hydrocarbon chains such as oleic acid is used in general. In the disclosure as well, therefore, a similar aggregation inhibitor is added to the solution of quantum dots and resin. In the solution under the presence of the aggregation inhibitor, the quantum dots are covered with the aggregation inhibitor. It is considered that the quantum dots are thus prevented from being aggregated (no fall in light emission intensity of the quantum dots is observed in this case).

In the method of the disclosure, as described above, the thin resin films in which the quantum dots are dispersed are formed from the solution of quantum dots and resin, and the platy structure is formed by laminating the thin resin films. Moreover, according to the configuration of the disclosure, the light emission intensity per irradiation light intensity can be more substantially improved than in the case where the solution of quantum dots and resin is directly cured into the platy structure, as mentioned already.

In another aspect of implementation of the disclosure, more specifically, the thin resin films in which the quantum dots are dispersed may be formed by spreading out the solution of quantum dots and resin into a thin-film shape to evaporate the organic solvent and cure the resin material. Accordingly, the thin resin films laminated into the platy structure may be thin films formed in such a manner. In the case of this configuration, while it is difficult and impractical to detect a state of the thin films that are being formed or have been formed, the organic solvent swiftly evaporates from the solution of quantum dots and resin, and the resin is cured before the quantum dots are aggregated. It is considered that the quantum dots are thus restrained from deteriorating.

Besides, as described above, in the case where the thin resin films in which the quantum dots are dispersed are formed by spreading out the solution of quantum dots and resin into a thin-film shape to evaporate the organic solvent and cure the resin material, the formed thin resin films have a thickness smaller than 1 mm, and typically a thickness of about several tenths of mm. Therefore, in the process of forming the thin resin films, the platy structure may be formed by applying the solution of quantum dots and resin, in a thin-film shape, onto the transparent or translucent film materials as described above, drying and curing the solution of quantum dots and resin there to form the thin resin films, and thus laminating the film materials on which the thin resin films are formed respectively. In still another aspect of implementation, more specifically, the thin resin films may be laminated to form the platy structure by repeating an operation of applying the solution of quantum dots and resin, in a thin-film shape, onto a transparent or translucent film material to form a thin resin film, further laminating a transparent or translucent film material on the formed thin resin film, and applying the solution of quantum dots and resin, in a thin-film shape, onto the laminated film material to form a thin resin film. Owing to this configuration, the platy structure with a plurality of laminated thin resin films can be formed well and easily.

In the aforementioned method of the disclosure, a fourth process of further drying the platy structure after formation of the platy structure may be performed to remove traces of the organic solvent more reliably from the platy structure formed by laminating the thin resin films.

Besides, for the purpose of protecting the platy structure formed by laminating the thin resin films, transparent or translucent film materials may be laminated on an upper surface and a lower surface of a laminated body constituted of the laminated thin resin films.

Furthermore, according to an experiment, it has been found out that the light emission intensity per irradiation light intensity in the completed fluorescent light-guiding plate is improved more when the process of forming and laminating the thin resin films is performed under the atmosphere of inert gas than when this process is performed in the atmosphere. This is considered to result from the fact that the oxygen in the atmosphere leads to a deterioration in the quantum dots or the aggregation inhibitor. Accordingly, in the aforementioned method, the process of forming and laminating the thin resin films is preferably performed under the atmosphere of an inert gas such as argon gas or nitrogen gas. Besides, with a view to preventing the contact of the oxygen in air with the thin resin films to the maximum possible extent, the film materials on which the thin resin films are formed or which are laminated on the thin resin films respectively are preferably films impermeable to oxygen.

By the way, in the fluorescent light-guiding plate, the fluorescence radiated from the quantum dots is preferably reflected as much as possible on the first surface and the second surface and concentrated onto the edge surfaces. Accordingly, a reflection mirror layer that reflects light instead of allowing permeation thereof may be laminated on or applied as the second surface on which no excitation light is incident. On the other hand, the light exciting the quantum dots from the outside needs to be incident on the first surface. Thus, the platy structure may be configured such that the refractive index thereof rises layer by layer from the first surface toward the second surface. According to this configuration, total reflection of light rays traveling from inside the platy structure toward the first surface is likely to occur. Therefore, the amount of fluorescence radiated from the quantum dots, permeating the first surface, and traveling to the outside can be reduced to the maximum possible extent.

Thus, according to the foregoing disclosure, the light emission intensity per irradiation light intensity is increased in the fluorescent light-guiding plate having the platy structure made of resin in which the quantum dots are dispersed as the fluorescent substance. Moreover, higher power generation efficiency is obtained in attaching photovoltaic cells to edge surfaces of the fluorescent light-guiding plate respectively. The fluorescent light-guiding plate according to the disclosure may be used for various purposes. For example, the fluorescent light-guiding plate is advantageously used as a member for converting sunlight into fluorescence and concentrating the fluorescence, in the photoelectric conversion device for photovoltaic power generation in JP 2022-062642 A or in the solar-pumped laser device described in JP 2017-168662 A.

Other objects and advantages of the disclosure will become apparent from the following description of preferred embodiments of the disclosure.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1A is a schematic perspective view of one aspect of a fluorescent light-guiding plate according to one of the embodiments;

FIG. 1B is a schematic perspective view of another aspect of the fluorescent light-guiding plate according to the present embodiment;

FIG. 1C is a schematic cross-sectional view of still another aspect of the fluorescent light-guiding plate according to the present embodiment;

FIG. 2A is a view schematically representing a process of forming thin resin films from a solution of quantum dots and resin, laminating the thin resin films, and forming a platy structure of the fluorescent light-guiding plate according to the present embodiment, showing a state where the solution of quantum dots and resin is placed on a film material;

FIG. 2B is a view schematically representing the process of forming the thin resin films from the solution of quantum dots and resin, laminating the thin resin films, and forming the platy structure of the fluorescent light-guiding plate according to the present embodiment, showing a state where the solution of quantum dots and resin is spread out into a thin-film shape on the film material;

FIG. 2C is a view schematically representing the process of forming the thin resin films from the solution of quantum dots and resin, laminating the thin resin films, and forming the platy structure of the fluorescent light-guiding plate according to the present embodiment, showing a state where a solvent is evaporated from the thin film-shaped solution of quantum dots and resin to cure the resin;

FIG. 2D is a view schematically representing the process of forming the thin resin films from the solution of quantum dots and resin, laminating the thin resin films, and forming the platy structure of the fluorescent light-guiding plate according to the present embodiment, showing a state where a next film material is laminated on the cured thin resin film;

FIG. 3 is a schematic cross-sectional view of a case where the fluorescent light-guiding plate according to the present embodiment is applied as a photoelectric conversion device;

FIG. 4A is a graphic view representing a current I and a power P that are obtained in photovoltaic cells in the case where the fluorescent light-guiding plate is irradiated with light with the photovoltaic cells attached to edge surfaces of the fluorescent light-guiding plate respectively, showing a platy structure formed by directly curing the solution of quantum dots and resin to the thickness of the fluorescent light-guiding plate;

FIG. 4B is a graphic view representing the current I and the power P that are obtained in the photovoltaic cells in the case where the fluorescent light-guiding plate is irradiated with light with the photovoltaic cells attached to the edge surfaces of the fluorescent light-guiding plate respectively, showing a platy structure formed by laminating thin resin films formed from the solution of quantum dots and resin according to the teachings of the present embodiment, with the concentration of quantum dots in the thin resin films being as high as in the case of FIG. 4A;

FIG. 4C is a graphic view representing the current I and the power P that are obtained in the photovoltaic cells in the case where the fluorescent light-guiding plate is irradiated with light with the photovoltaic cells attached to the edge surfaces of the fluorescent light-guiding plate respectively, showing the platy structure formed by laminating the thin resin films formed from the solution of quantum dots and resin according to the teachings of the present embodiment, with the total amount of quantum dots in the platy structure being as large as in the case of FIG. 4A;

FIG. 5A is a schematic perspective view of a state where the photovoltaic cells are attached to the edge surfaces of the fluorescent light-guiding plate respectively;

FIG. 5B is a schematic cross-sectional view of part of the fluorescent light-guiding plate for illustrating a mechanism according to which the fluorescence of the quantum dots is concentrated onto the fluorescent light-guiding plate in the case where the fluorescent light-guiding plate is irradiated with sunlight;

FIG. 6A is a schematic cross-sectional view of a state where a mold is filled with the solution of quantum dots and resin, in a process of directly curing the solution of quantum dots and resin to the thickness of the fluorescent light-guiding plate;

FIG. 6B is a schematic cross-sectional view of the platy structure of the fluorescent light-guiding plate obtained by curing the solution of quantum dots and resin in the mold of FIG. 6A;

FIG. 6C is a view schematically representing a predicted state of the quantum dots in the solution of quantum dots and resin; and

FIG. 6D is a view schematically representing a predicted state of the quantum dots inside the platy structure obtained by directly curing the solution of quantum dots and resin to a certain thickness.

### DETAILED DESCRIPTION OF EMBODIMENTS

Basic Configuration of Fluorescent Light-Guiding Plate

Referring to FIG. 5A and FIG. 5B, a fluorescent light-guiding plate 1 as a subject matter of one of the embodiments is basically a member of a platy structure 2 in which a fluorescent substance is dispersed. Specifically, as shown in the drawings, the platy structure 2 of the fluorescent light-guiding plate 1 is defined by a light-receiving surface 2a (a front surface or a first surface) that receives light SL such as sunlight, a back surface 2b (a second surface) thereof, and edge surfaces 2e that connect the light-receiving surface 2a and the back surface 2b to each other, and is formed of a material in which a fluorescent substance 6 is dispersed and which is higher in refractive index than an outside space. While the fluorescent substance 6 may be, for example, any fluorescent pigment or the like, quantum dots with long absorption wavelength, short light emission wavelength, and high quantum efficiency are used more advantageously. Besides, a matrix of the platy structure 2 may be any transparent or translucent material that is higher in refractive index than air. For example, fluorine resin (with the refractive index of 1.33), high-refractive polymethyl methacrylate resin (with the refractive index of 1.60), polycarbonate resin (with the refractive index of 1.59), polyester resin (with the refractive index of 1.60), acrylic resin (with the refractive index of 1.49 to 1.53), silicon resin (with the refractive index of 1.43), quartz glass (with the refractive index of 1.54 to 1.55), or the like is used as the matrix of the platy structure 2. Moreover, as shown in the drawings, when the light SL enters from the light-receiving surface 2a, the fluorescent substance 6 inside is excited to radiate fluorescence FL in all the directions. Since the platy structure 2 is higher in refractive index than the outside space, total reflection of the fluorescence FL occurs on the light-receiving surface 2a and the back surface 2b. Thus, except for some light rays at an incidence angle smaller than a critical angle with respect to the light-receiving surface 2a and the back surface 2b, the fluorescence FL is repeatedly reflected on the light-receiving surface 2a and the back surface 2b, and reaches the edge surfaces 2e. According to this configuration, the light received by the light-receiving surface 2a over a large area can be concentrated onto the edge surfaces 2e with a smaller area after being converted into fluorescence through the fluorescent substance 6, so the condensation of energy on the edge surfaces 2e is enabled. Accordingly, with the fluorescent light-guiding plate 1 as shown in the drawings, the density of light that arrives with low energy density, such as sunlight, can be made high. For example, as shown in the drawings, when photoelectric cells 3 are arranged on the edge surfaces 2e of the platy structure 2 respectively to convert optical energy into electric energy, optical energy can be recovered through the mere use of the photoelectric cells with a smaller dimension.

Typical Method of Forming Platy Structure of Fluorescent Light-Guiding Plate

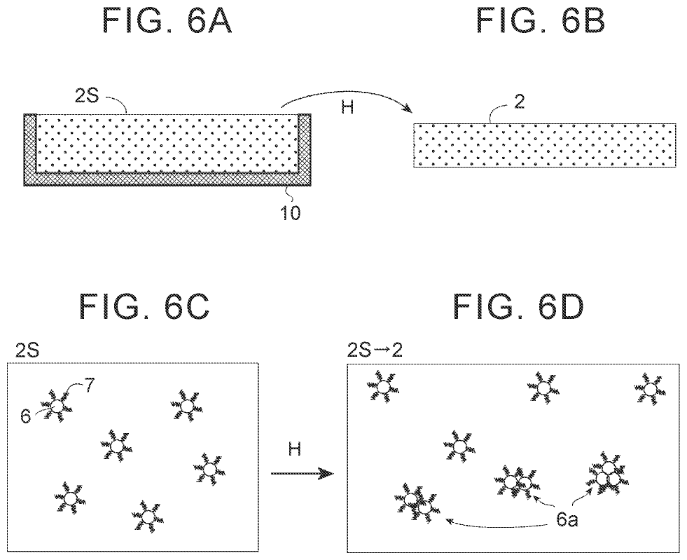

In forming the fluorescent light-guiding plate described above, typically, a resin solution 2S with an organic solvent such as toluene in which the fluorescent substance is dispersed and a resin material is dissolved is poured into a mold 10 with a depth corresponding to the thickness of the platy structure 2, the organic solvent in the resin solution 2S is evaporated in the mold 10, and the resin material is cured (H) and solidified into the shape of the platy structure 2, thus forming the platy structure 2, as schematically depicted in FIG. 6A and FIG. 6B.

In this regard, according to the studies conducted by the inventors of the disclosure, it has been observed that the light emission intensity per irradiation light intensity (the ratio of the light intensity obtained on the edge surfaces of the platy structure to the intensity of the light with which the light-receiving surface of the platy structure has been irradiated) is substantially lower than in the case of the resin solution 2S, in the solidified platy structure 2, especially in the case where quantum dots are adopted as the fluorescent substance. This is considered to result from a deterioration in the quantum dots, namely, a fall in the intensity of the fluorescence radiated from the quantum dots per intensity of irradiation light. One of the causes of this deterioration in the quantum dots is considered to be the aggregation of the quantum dots. More specifically, a fatty acid having hydrocarbon chains such as oleic acid is usually added, as an aggregation inhibitor 7, to a solution in which quantum dots are dispersed, to avoid the aggregation of the quantum dots, as schematically depicted in FIG. 6C. The aggregation inhibitor 7 is considered, because of the chemical properties thereof, to cover the periphery of each of the quantum dots and hence prevent the quantum dots from being aggregated. However, as described above, when the resin solution (the solution of quantum dots and resin) 2S in which the quantum dots are dispersed is cured, the organic solvent gradually evaporates over a certain length of time. Therefore, it is considered that the aggregation inhibitor 7 desorbs from the peripheries of the quantum dots 6 with the quantum dots 6 remaining removable, as the ratio of the organic solvent decreases slowly, thus allowing the quantum dots 6 to form aggregates 6a. Then, when this aggregation of the quantum dots occurs, the amount of fluorescence generated for the optical energy received on the light-receiving surface 2a of the fluorescent light-guiding plate 1 falls, so the amount of the optical energy transmitted to the edge surfaces 2e falls. Accordingly, the presence of a configuration capable of avoiding the aggregation of the quantum dots when the solution of quantum dots and resin is cured as described above is advantageous.

### Improvement in Platy Structure of Fluorescent Light-Guiding Plate According to Present Embodiment

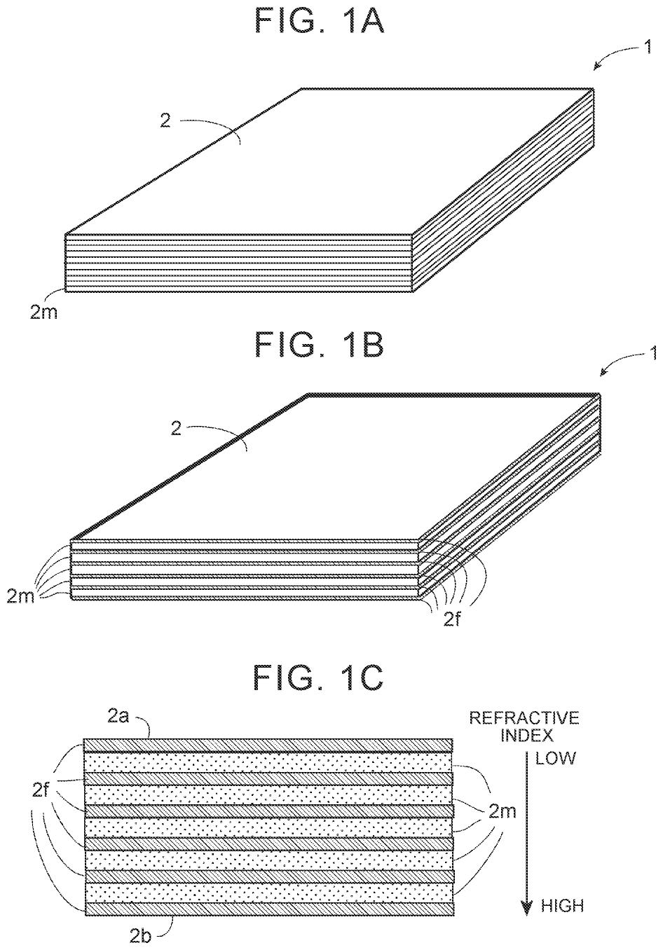

The inventors of the disclosure have conducted various studies as to a method of avoiding a deterioration in quantum dots resulting from the aggregation of the quantum dots as described above. As a result, it has been found out that the degree of deterioration in the quantum dots is substantially reduced when the solution of quantum dots and resin is cured into thin resin films 2m that are smaller in thickness than the platy structure 2 and the thin resin films 2m are laminated to form the platy structure 2 as shown in FIG. 1A, instead of curing the solution of quantum dots and resin to the thickness of the platy structure 2 from the beginning. This is considered to result from the fact that the time needed to cure each of the thin films is much shorter when the thin resin films are formed from the solution of quantum dots and resin than when the solution of quantum dots and resin is cured in a mold of a certain depth (it is considered to be difficult and impractical to detect the state of the quantum dots in the thin films) as shown in FIG. 6A, and that the resin is cured, the quantum dots are fixed, and the individual quantum dots remain dispersed before the aggregation of the quantum dots.

Specifically, in the aforementioned platy structure of the fluorescent light-guiding plate according to the present embodiment, any quantum dots that can absorb the light with a band of wavelength of sunlight and are chemically stable in an organic solvent or resin may be adopted as the quantum dots. For example, CdSe, CdTe, PbS, perovskite quantum dots (CsPbX₃, X=Cl, Br, I etc.) or the like may be utilized as the quantum dots. A matrix resin of the thin resin films may be any transparent or translucent solid resin that exhibits appropriate rigidity when cured, and may be, for example, a fluorine resin such as 4 ethylene fluoride-ethylene copolymer (ETFE) or polymethyl methacrylate resin, but is not limited thereto. Incidentally, as described already, the resin is preferably higher in refractive index than the outside (air) to the maximum possible extent such that a maximum amount of fluorescence from inside the platy structure is reflected on the light-receiving surface 2a and the back surface 2b. The thin resin films may have any thickness smaller than 1 mm, specifically a thickness of several tenths of mm, and typically a thickness of about 0.3 mm or the like. The thickness of the platy structure may be arbitrarily set depending on the purpose of use.

Incidentally, when the platy structure 2 is formed by laminating the thin resin films 2m, the thin resin films 2m may be laminated while being placed or stuck on transparent or translucent film materials 2f respectively, as depicted in FIG. 1B. That is, the thin resin films 2m and the film materials 2f may be alternately laminated in the platy structure 2. Any transparent or translucent film materials such as polyester films may be used as the film materials 2f. The thickness of the film materials 2f may be, for example, 0.1 mm, but is not limited thereto. By handling the thin resin films 2m placed or stuck on the film materials 2f respectively, the operation of lamination is facilitated, and the risk of the thin resin films 2m being ruptured during lamination is reduced, which also leads to an improvement in structural stability of the platy structure 2. Besides, with a view to protecting the thin resin films 2m, the film materials 2f are preferably laminated on outermost surfaces (the light-receiving surface 2a and the back surface 2b) of the platy structure 2 respectively. Furthermore, with a view to protecting the quantum dots from the oxygen in air (it is observed that the quantum dots deteriorate due to oxygen as well), the film materials 2f preferably exhibit impermeability to oxygen. Moreover, as described already, the film materials 2f are preferably higher in refractive index than the outside (air) to the maximum possible extent such that a maximum amount of fluorescence from inside the platy structure 2 is reflected on the light-receiving surface 2a and the back surface 2b.

Besides, as a more advantageous aspect, a material may be selected such that the refractive index increases layer by layer from the light-receiving surface 2a toward the back surface 2b, as shown in FIG. 1C, in the platy structure 2 configured as the laminated body of the thin resin films 2m and the film materials 2f. According to this configuration, permeation of the fluorescence from the quantum dots from the light-receiving surface 2a side is made difficult, so the fluorescence can be more reliably concentrated onto the edge surfaces 2e. A reflection layer impermeable to light may be laminated on the back surface 2b to enable the prevention of leakage of the fluorescence from the back surface 2b.

### Method of Forming Platy Structure of Fluorescent Light-Guiding Plate According to Present Embodiment

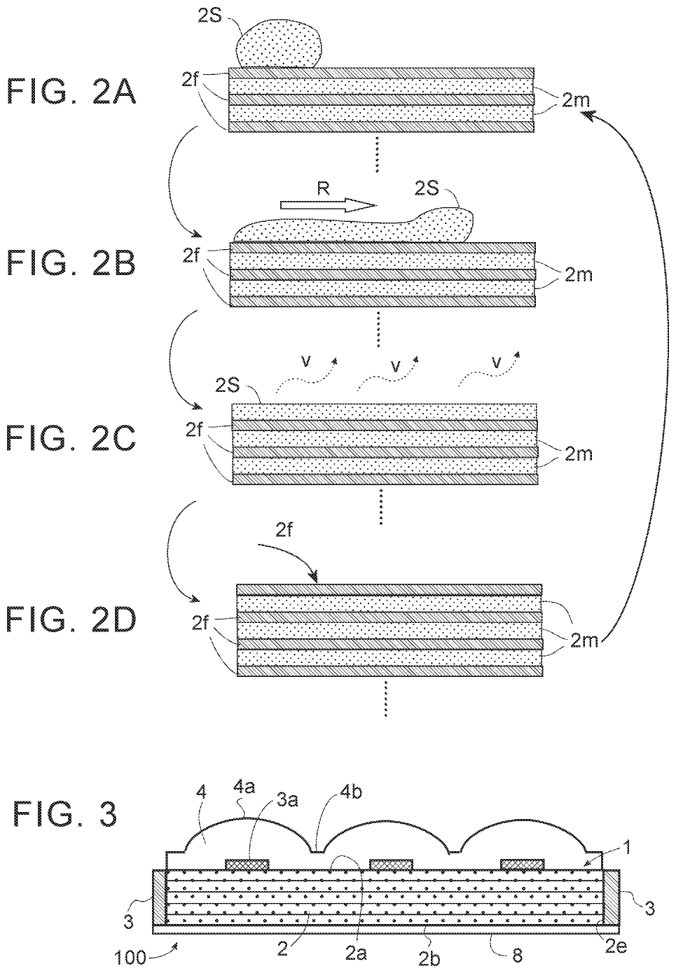

The formation of the platy structure 2 through lamination of the thin resin films 2m in the present embodiment may be achieved through any method. For example, in one aspect of the method of forming the platy structure 2 of the fluorescent light-guiding plate 1 according to the present embodiment, formation of the thin resin films 2m on the film materials 2f and lamination of the film materials 2f on the thin resin films 2m may be repeated with reference to FIG. 2A, FIG. 2B, FIG. 2C, and FIG. 2D. Specifically, in the case of this aspect, the solution 2S of quantum dots and resin is first dropped on one of the film materials 2f (FIG. 2A), and is spread out into a thin-film shape on the film material 2f through the use of an applicator R or the like (FIG. 2B). It should be noted herein that the solution 2S of quantum dots and resin is prepared by dispersing quantum dots and an aggregation inhibitor, and then dissolving a resin material that turns into resin when cured, in a volatile organic solvent that is usually used in this field, such as toluene, as described already. The concentrations of the quantum dots, the aggregation inhibitor, and the resin material may be adjusted through adaptation. In the present embodiment, the solution 2S of quantum dots and resin is spread out into the thin-film shape, so the concentrations may be adjusted such that a viscosity allowing the solution 2S to be spread out through the use of the applicator R is obtained. When the concentration of quantum dots is too high, the light emission intensity of quantum dots per irradiation light intensity falls. Therefore, the concentration may be adjusted to optimize the light emission intensity per irradiation light intensity, through an experiment or the like. The solution 2S spread out into the thin-film shape may have any thickness smaller than 1 mm, and specifically a thickness of several tenths of mm.

After being spread out on the film materials 2f, the solution 2S of quantum dots and resin is settled. In the meantime, the organic solvent evaporates (v), the resin material is cured, and the thin resin films 2m are solidified (FIG. 2C). In this case, the solution 2S is small in thickness, so the organic solvent substantially evaporates swiftly, for example, in about one minute, and the resin material is cured to form the solidified thin resin films 2m. After that, the new film material 2f is laminated on the solidified thin resin film 2m (FIG. 2D), and the aforementioned process starting from FIG. 2A is repeated. Moreover, the processing cycle in FIGS. 2A to 2D may be repeated until the thickness of the entire laminated body of the thin resin films 2m and the film materials 2f becomes equal to the thickness required of the platy structure 2.

After that, although not shown in the drawings, the laminated body of the thin resin films 2m and the film materials 2f may be settled in a dry state to remove traces of the organic solvent in the thin resin films 2m. Then, after the laminated body is dried, the peripheries thereof are cut according to an arbitrary method to trim the edge surfaces 2e. After that, photoelectric cells or the like may be attached to the edge surfaces 2e respectively.

Incidentally, the quantum dots in the solution 2S are likely to deteriorate upon coming into contact with oxygen (possibly due to oxidation of the aggregation inhibitor or the like). It is preferable that the aforementioned series of processes be performed under the atmosphere of an inert gas such as argon gas or nitrogen gas. According to an experiment on power generation efficiency that will be described later, it has been found out that the power generation efficiency increases when the aforementioned processes are performed under the atmosphere of inert gas.

### Application Examples

As described already, the fluorescent light-guiding plate 1 of the present embodiment is advantageously used in, for example, a photoelectric conversion device 100 as exemplified in FIG. 3. Referring to FIG. 3, the photoelectric conversion device 100 includes the fluorescent light-guiding plate 1 configured as the platy structure 2, photoelectric cells 3a placed on an upper surface 2a of the platy structure 2, a lens layer 4 superimposed on the upper surface 2a and the photoelectric cells 3a, and the photoelectric cells 3 arranged on the edge surfaces 2e of the platy structure 2 respectively. Incidentally, as shown in the drawings, each of the power generated by the photoelectric cells 3 and the power generated by the photoelectric cells 3a may be taken out to the outside through a power line (not shown).

In this configuration, the fluorescent light-guiding plate 1 is used as a substrate on which the photoelectric cells 3a that absorb sunlight to generate power are arranged, and at the same time, performs the functions of receiving the light with which the photoelectric cells 3a have not been irradiated, converting the light into fluorescence through the use of the quantum dots dispersed inside the fluorescent light-guiding plate 1, and concentrating the fluorescence onto the edge surfaces 2e, as described already. Incidentally, a reflection mirror 8 that is impermeable to light and reflects light may be applied as a lower surface 2b of the fluorescent light-guiding plate 1. Thus, permeation of light from the lower surface 2b is prevented, and a larger amount of light can reach the edge surfaces 2e.

Each of the photoelectric cells 3a placed on the upper surface 2a of the fluorescent light-guiding plate 1 may be any type of photovoltaic cell or photoelectric conversion element that absorbs light components of sunlight to generate power. As mentioned already, the band of wavelength of sunlight is wide. Besides, in the example shown in the drawing, sunlight SL is concentrated by lens regions 4a to irradiate the photoelectric cells 3a, so the photoelectric cells that have a wide band of wavelength enabling the absorption of light and that exhibit high power generation efficiency even when irradiated with light of relatively high intensity are used advantageously, as will be described later. Specifically, III-V group multi-junction photovoltaic cells may be selected as the photoelectric cells 3a. Incidentally, other types of photoelectric cells, for example, CIS photovoltaic cells, crystalline silicon photovoltaic cells, amorphous silicon photovoltaic cells, or perovskite photovoltaic cells may also be adopted as the photoelectric cells 3a.

The lens layer 4 may adopt a layered structure having the lens regions 4a formed in such a manner as to concentrate sunlight and irradiate each of the photoelectric cells 3a with the concentrated sunlight, and connection regions 4b that connect the lens regions 4a to one another. The lens layer 4 may be formed of a transparent or translucent material that is higher in refractive index than air. Specifically, silicon resin (with the refractive index of 1.43), low-refractive polymethyl methacrylate (with the refractive index of 1.40), or soda glass (with the refractive index of 1.51) may be adopted as the material. Incidentally, a material that is lower in refractive index than the platy structure 2 may be preferably selected as the material of the lens layer 4, such that the light that has entered the fluorescent light-guiding plate 1 and the fluorescence radiated by the fluorescent light-guiding plate 1 are sealed in the platy structure 2. Besides, in the lens layer 4, the lens regions 4a are formed in such a manner as to concentrate the light reaching outer surfaces thereof (surfaces on the opposite side of those facing or located close to the fluorescent light-guiding plate 1, namely, upper surfaces in the drawing) onto the photoelectric cells 3a respectively. The lens regions 4a may be formed as spherical lenses, but may be preferably formed as non-spherical, non-symmetrical lenses that are adjusted in such a manner as to be able to concentrate a maximum amount of light components incident on lens surfaces at various angles of incidence, including the sunlight scattered by clouds and air or the sunlight reflected or scattered by buildings and the like as well as the direct light arriving as parallel light rays from sunlight, onto the photoelectric cells 3a.

As the photoelectric cells 3 located on the edge surfaces 2e of the fluorescent light-guiding plate 1 respectively to absorb the fluorescence (and sunlight) emitted from the edge surfaces 2e and generate power, any types of photovoltaic cells or photoelectric conversion elements that absorb light components in the band of wavelength of fluorescence may be adopted mainly. For example, CIS photovoltaic cells, crystalline silicon photovoltaic cells, amorphous silicon photovoltaic cells, or perovskite photovoltaic cells may be selected (III-V group multi-junction photovoltaic cells that are more expensive than these cells may also be used).

Incidentally, the device 100 can be preferably transformed to a certain extent, in accordance with the shape of an object at a place where the device 100 is installed, for example, the roof of a movable body. Thus, the fluorescent light-guiding plate 1 and the lens layer 4 may be formed of a flexible material, and it may be possible to curve the entire device 100.

In operation, when the lens layer 4 is irradiated with sunlight from above, the light incident on the lens regions 4a is first concentrated onto the photoelectric cells 3a through a lens effect, and the photoelectric cells 3a generate power upon receiving the light. In this case, typically, the lens regions 4a are formed in such a shape that light rays (sunlight) incident along optical axes thereof (in a direction perpendicular to surfaces of central regions of the lens regions 4a), namely, light rays at an angle of incidence of about 0° are refracted toward light-receiving surfaces (upper surfaces in the drawing) of the photoelectric cells 3a respectively. However, with increases in an angle θ of incidence of light rays incident on the lens regions 4a, the amount of light passing through the lens regions 4a and failing to reach the light-receiving surfaces of the photoelectric cells 3a increases. Besides, in the lens layer 4, as is understood from the drawing, in the case where the connection regions 4b exist between the adjacent lens regions 4a respectively, the light incident on those regions does not hit the photoelectric cells 3a either, and hence is not utilized to generate power. Thus, in the device 100 shown in the drawing, the fluorescent light-guiding plate 1 receives the light that has failed to reach the light-receiving surfaces of the photoelectric cells 3a, the quantum dots dispersed in the plate are excited by the sunlight to radiate fluorescence while failing to reach the photoelectric cells 3a, and the radiated fluorescence propagates to the edge surfaces 2e, is concentrated onto the edge surfaces 2e, and is recovered as power by the photoelectric cells 3 arranged on the edge surfaces 2e respectively.

Thus, according to the configuration as described above, even when some of the light rays concentrated by the lens layer 4 fail to reach the photoelectric cells 3a, the energy thereof can be taken out as power in the photoelectric cells 3 via the fluorescent light-guiding plate 1. It is therefore safe to conclude that the robustness of sunlight incident on the lens layer 4 with respect to the angle of incidence has been enhanced. Furthermore, in the case where the connection regions 4b exist between the adjacent lens regions 4a of the lens layer 4 respectively, the energy of the sunlight that has entered those regions is also converted into power, so the efficiency of energy conversion is further enhanced.

### Experimental Examples

The operations and effects of the present embodiment described above have been confirmed by the following experiments. Incidentally, it should be understood that the following experimental examples exemplify the validity of the present embodiment, and are not intended to limit the scope of the disclosure.

In the experiments, in simple terms, a solution of quantum dots and resin with an organic solvent in which quantum dots and a resin material are dispersed was prepared. A platy sample (a conventional example) obtained by pouring the solution of quantum dots and resin into a mold of a certain depth and curing the solution directly into a platy structure, and platy samples (the present examples) formed into platy structures by laminating thin resin films formed from a solution of quantum dots and resin on transparent films respectively were prepared. Then, in order to evaluate the light emission intensity per irradiation light intensity, photoelectric cells were attached to edge surfaces of the platy samples prepared respectively, the respective platy samples were irradiated with pseudo-sunlight through the use of a solar simulator, amounts of generated power were measured, and values of power generation efficiency were calculated and compared with each other. Incidentally, for the sake of comparison, values of power generation efficiency were calculated in a similar manner in the state of the solution of quantum dots and resin as well.

With regard to the preparation of the platy samples, in more detail, as for the conventional example, a solution of quantum dots and resin was prepared by first mixing 2.13 ml of a solution of quantum dots with toluene in which quantum dots PbS are dispersed at 10000 ppm, 10 ml of toluene, 36 g of fluorine resin (Lumiflon® 910LM), and 12 g of hexamethylene diisocyanate-type polyisocyanate (Duranate®) with one another, and stirring the mixture for 10 minutes. The prepared solution of quantum dots and resin was poured into a rectangular mold with a depth of 4 mm, and was settled in a dry state at room temperature for 24 hours to be cured. Incidentally, when the solution of quantum dots and resin is cured, toluene evaporates. Therefore, the thickness of a formed platy member became about 3 mm. After that, the formed platy member was taken out from the mold, and four lateral surfaces thereof were cut off by a pencil cutter to form edge surfaces. General-purpose photoelectric cells (crystalline silicon photovoltaic cells) were glued to the edge surfaces respectively through the use of an instant adhesive (α, α-cyanoacrylate ester).

With regard to the present examples, as the first example, the same solution of quantum dots and resin as in the conventional example was prepared, the solution of quantum dots and resin was dropped onto a transparent polyester film material that has a thickness of about 0.1 mm and is impermeable to gas (Lumirror® film T60), and the solution of quantum dots and resin was applied through the use of an applicator of 125 μm and settled at room temperature to form a thin resin film. Then another polyester film material was further laminated on the formed thin resin film. The formation of thin resin films through the dropping, application, and drying of the solution of quantum dots and resin was repeated until the thickness of the laminated body became 3 mm. Incidentally, the aforementioned film material was laminated on the uppermost surface. After that, with a view to removing traces of toluene in the cured resin, the laminated body was settled for 30 minutes at room temperature, four lateral surfaces thereof were cut off through the use of a pencil cutter to form edge surfaces, and general-purpose photoelectric cells were glued to the entire edge surfaces respectively through the use of an instant adhesive to create a platy sample, as in the case of the conventional example. Incidentally, the aforementioned series of operations was entirely performed in a glove box under the atmosphere of argon. In this state, the upper and lower surfaces of the platy member are covered with the film materials respectively, and the edge surfaces are covered with the instant adhesive and the photoelectric cells respectively. Therefore, even when the platy member is exposed to air, resin does not come into contact with air. In the case of the first example, the concentration of quantum dots in resin is the same as in the case of the conventional example.

Besides, as the second example, the same solution of quantum dots and resin as in the conventional example, with 4.26 ml of a solution of quantum dots and 8 ml of toluene was prepared in the same manner, the formation and lamination of thin resin films and the gluing of photoelectric cells were carried out in the same manner as in the first example, through the use of the prepared solution of quantum dots and resin, to create a platy sample. In the case of the second example, the total amount of quantum dots in resin is the same as in the case of the conventional example.

In measuring an amount of power generation in the state of the solution of quantum dots and resin, the same solution of quantum and resin as in the conventional example was poured into a glass mold (with a depth of 3 mm) around which photoelectric cells are glued, to obtain a sample for measurement.

In evaluating the light emission intensity of the platy sample per irradiation light intensity, each of the platy samples was irradiated with pseudo-sunlight with a spectrum of AM 1.5 at 100 mW/cm² through the use of a solar simulator, and values of generated power (mW) of the photoelectric cells attached to the four edge surfaces of each of the platy samples were measured, and a value of power generation efficiency was calculated from the measured values according to the following equation.

Power Generation Efficiency (%)=Pt (mW)/(100 (mW/cm²)×A (cm²)) (1)

In this case, Pt denotes the total power generated by the photoelectric cells, and A denotes the area of the light-receiving surface of each of the platy samples. The power generation efficiency (%) corresponds to the ratio of light intensity obtained on the edge surfaces of the platy structure to the intensity of light with which the light-receiving surface of the platy structure was irradiated (the light emission intensity per irradiation light intensity).

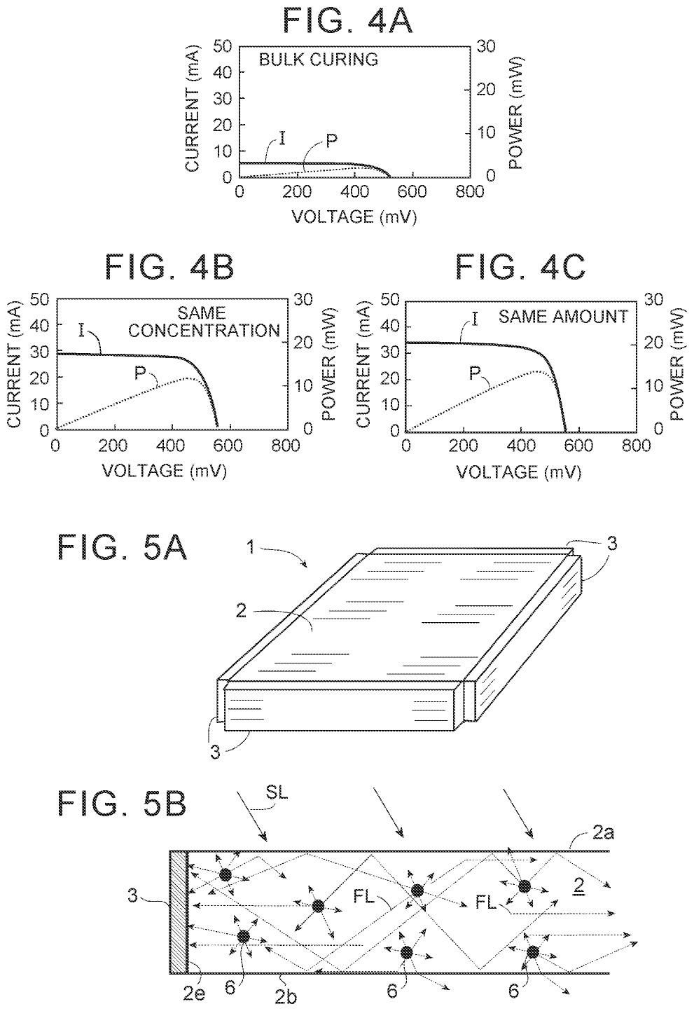

In the obtained results, referring first to the characteristics of the generated power P and a generated current I with respect to a generated voltage in the photoelectric cells attached to each of the platy samples in FIGS. 4A to 4C, it is understood that the generated power and the generated current are much larger in both the first example shown in FIG. 4B and the second example shown in FIG. 4C in the present embodiment than in the conventional example shown in FIG. 4A. As for the maximum values of power generation efficiency in the respective platy samples, while the maximum value of power generation efficiency was 0.5% in the conventional example, the maximum value of power generation efficiency was 5% in the first example in which the concentration of quantum dots is the same as in the conventional example, and the maximum value of power generation efficiency was 6% in the second example in which the total amount of quantum dots is the same as in the conventional example. This is equivalent to an improvement of 10 to 12 times in the light emission intensity per irradiation light intensity in the cases of the present examples in comparison with the conventional example. Besides, the maximum value of power generation efficiency was 7% in the state of the solution of quantum dots and resin. It is therefore understood that the quantum dots are far more restrained from deteriorating in the case of the present embodiment than in the conventional example. It has been demonstrated from these results that the light emission intensity per irradiation light intensity can be held closer to that in the state of the solution of quantum dots and resin since the platy structure is configured by laminating the thin resin films formed from the solution of quantum dots and resin according to the teachings of the present embodiment, in the fluorescent light-guiding plate.

Thus, as described above, in the fluorescent light-guiding plate having the platy structure established by laminating the thin resin films in which the quantum dots are dispersed according to the present embodiment, the light emission intensity per irradiation light intensity can be held higher while hardly causing a deterioration in the quantum dots that occurs when the solution of quantum dots and resin is directly cured to the thickness of the platy structure. The fluorescent light-guiding plate of the present embodiment is expected to be advantageously used in a photoelectric conversion device for sunlight and a solar-pumped laser device.

The foregoing description has been given in relation to the embodiments of the disclosure, but it would be obvious that those skilled in the art can easily carry out many modifications and alterations, and that the disclosure is not limited to the embodiments exemplified above but is applicable to various devices without departing from the concept of the disclosure.

What is claimed is:

1. A method of manufacturing a fluorescent light-guiding plate that is defined by a first surface, a second surface, and edge surfaces connecting peripheral edges of the first surface and the second surface to each other, that has a platy structure in which quantum dots that absorb at least one or some of components of sunlight and radiate fluorescence are internally dispersed and which is formed of a material different in refractive index from an outside, and that allows the fluorescence radiated from the quantum dots to be concentrated onto the edge surfaces and emitted when the sunlight is incident from the first surface, the method comprising:
a first process of preparing a solution of quantum dots and resin with an organic solvent in which the quantum dots covered with an aggregation inhibitor and a resin material are dispersed;
a second process of forming thin resin films in which the quantum dots are dispersed, from the solution of quantum dots and resin; and
a third process of laminating the thin resin films to form the platy structure.

2. The method according to claim 1, wherein
the solution of quantum dots and resin is spread out into a thin-film shape to evaporate the organic solvent, and the resin material is cured to form the thin resin films, in the second process.

3. The method according to claim 2, wherein
the solution of quantum dots and resin is applied, in the thin-film shape, onto transparent or translucent film materials to form the thin resin films respectively in the second process, and
the film materials on which the thin resin films are formed respectively are laminated to form the platy structure in the third process.

4. The method according to claim 3, wherein
the thin resin films are laminated to form the platy structure, by repeatedly laminating the transparent or translucent film materials on the thin resin films formed in the second process respectively, and applying the solution of quantum dots and resin, in the thin-film shape, onto the laminated film materials to form the thin resin films respectively.

5. The method according to claim 1, further comprising:
a fourth process of further drying the platy structure after formation of the platy structure.

6. The method according to claim 1, wherein
transparent or translucent film materials are laminated on an upper surface and a lower surface of a laminated body constituted of the laminated thin resin films, respectively.

7. The method according to claim 1, wherein
the second process and the third process are performed under an atmosphere of inert gas.

8. The method according to claim 2, wherein
the film materials are films impermeable to oxygen.

9. The method according to claim 1, wherein
each of the thin resin films is formed with a thickness smaller than 1 mm.

10. The method according to claim 1, wherein
the refractive index is raised layer by layer from the first surface toward the second surface, in the platy structure.

11. A fluorescent light-guiding plate that is defined by a first surface, a second surface, and edge surfaces connecting peripheral edges of the first surface and the second surface to each other, that has a platy structure in which quantum dots that absorb at least one or some of components of sunlight and radiate fluorescence are internally dispersed and which is formed of a material different in refractive index from an outside, and that allows the fluorescence radiated from the quantum dots to be concentrated onto the edge surfaces and emitted when the sunlight is incident from the first surface, wherein
the platy structure is established by laminating a plurality of thin resin films in which the quantum dots are dispersed.

12. The fluorescent light-guiding plate according to claim 11, wherein
the platy structure is configured such that the thin resin films and a plurality of transparent or translucent film materials are laminated alternately.

13. The fluorescent light-guiding plate according to claim 11, wherein
the thin resin films are formed by spreading out a solution of quantum dots and resin with an organic solvent in which the quantum dots covered with an aggregation inhibitor and a resin material are dispersed, into a thin-film shape, to evaporate the organic solvent and cure the resin material.

14. The fluorescent light-guiding plate according to claim 13, wherein
the platy structure is formed such that the thin resin films are laminated, by repeatedly laminating another transparent or translucent film material on one of the thin resin films formed by applying the solution of quantum dots and resin, in the thin-film shape, onto one of the transparent or translucent film materials, and applying the solution of quantum dots and resin, in the thin-film shape, onto the laminated film material to form another one of the thin resin films.

15. The fluorescent light-guiding plate according to claim 12, wherein
the film materials are films impermeable to oxygen.

16. The fluorescent light-guiding plate according to claim 11, wherein
each of the thin resin films has a thickness smaller than 1 mm.

17. The fluorescent light-guiding plate according to claim 11, wherein
the refractive index rises layer by layer from the first surface toward the second surface, in the platy structure.
